(19) United States
(12) Patent Application Publication
(10) Pub. No.: US 2007/0045648 A1
(43) Pub. Date: Mar. 1, 2007

(54) Package structure of light emitting diode

(75) Inventor: Feng-Li Lin, Taishan Township (TW)

Correspondence Address: BIRCH STEWART KOLASCH & BIRCH, PO BOX 747, FALLS CHURCH, VA, 22040-0747, US

(73) Assignee: GIGNO TECHNOLOGY CO., LTD.

(21) Appl. No.: 11/493,769

(22) Filed: Jul. 27, 2006

(30) Foreign Application Priority Data
Aug. 29, 2005 (TW) 094129557

(51) Int. Cl. H01L 33/00

(52) U.S. Cl. 257/99

(57) ABSTRACT

A package structure of a light emitting diode for outputting a target peak wavelength includes a carrier, a first die and a second die. The first die is disposed on the carrier. The first die has a first peak wavelength greater than the target peak wavelength. The second die is disposed on the carrier and has a second peak wavelength smaller than the target peak wavelength. The first die and the second die emit light of the same color group.

### BACKGROUND OF THE INVENTION

1. Field of Invention

The invention relates to a package structure of a diode, and, in particular, to a package structure of a light emitting diode.

2. Related Art

A light emitting diode (LED) is a light emitting element made of a semiconductor material and has two electrode terminals. A very small voltage is applied between the terminals, and the residual energy may be released in the form of light when the voltage works in conjunction with the electronic holes.

Different from the typical incandescent light bulb, the light emitting diode emits the fluorescent light and thus has the advantages of low power consumption, long lifetime, no warm-up time, and quick response speed. In addition, the LED has a small size, can resist the vibration and is suitable for the mass production. Therefore, the LED can be made very small or the LEDs may be arranged in an array to form an array device. At present, the LED has been widely used in the indicators and display devices of information, communication and consumer electronic products, and thus becomes the important and indispensable element in the daily life. Recently, the light emitting diode is further applied to the backlight source of a liquid crystal display (LCD) and tends to replace the conventional cold cathode fluorescent lamp gradually.

In the prior art, the die in the package structure of the light emitting diode is usually manufactured by the semiconductor epitaxy process. The light emitted by the die has the wavelength determined by the material of the epitaxial layer. Therefore, the cost of the epitaxy process is the highest one among the LED manufacturing processes.

As shown in FIG. 1, a semiconductor wafer 1 may have a plurality of LED dies D, and the suitable dies D may be picked and packaged after the wafer 1 has been cut. Thus, the package structure of the light emitting diode can be applied to various products.

The wafer is controlled under the same manufacturing process such that all dies output the light with the same target color. However, the dies manufactured in the same batch or even on the same wafer may have great wavelength variations. For example, if the target color of the same batch of dies is green, the optical peak wavelength of one of the dies may be 500 nm, and the optical peak wavelength outputted by another one of the dies may be 506 nm.

In some application fields such as the backlight module of the liquid crystal display or the high-class vehicle lamp, however, a plurality of light emitting diodes having substantially the same wavelength must be provided. Thus, the peak wavelength of the die must be controlled strictly. That is, the peak wavelengths of the dies manufactured in the same batch or on the same wafer may fall within a narrow range to meet the quality control standard of the manufacturer such that the dies may be selected as the good dies to be used in the product. The dies having the wavelength out of the narrow range usually become the bad dies which cannot be used. Consequently, all dies on the same wafer cannot be used, and the die availability is not high. Therefore, the manufacturing cost of the package structure of the light emitting diodes cannot be reduced, and the material is thus wasted.

Therefore, it is an important subject of the invention to provide a package structure of a light emitting diode capable of solving the above-mentioned problems of the low die availability on the wafer and the high manufacturing cost.

### SUMMARY OF THE INVENTION

In view of the foregoing, the invention is to provide a package structure of a light emitting diode capable of outputting light with two or more than two target peak wavelengths to enhance the die availability and reduce the manufacturing cost.

To achieve the above, the invention discloses a package structure of a light emitting diode for outputting a target peak wavelength. The package structure includes a carrier, a first die and a second die. The first die is disposed on the carrier and has a first peak wavelength greater than the target peak wavelength. The second die is disposed on the carrier and has a second peak wavelength smaller than the target peak wavelength. The first and second peak wavelengths pertain to the same color group.

As mentioned above, the LED package structure of the invention has a plurality of dies having the first peak wavelength and the second peak wavelength, which pertain to the same color group. Compared to the prior art, a plurality of dies having the properly matched wavelengths can be picked in the LED package structure of the invention, so that the dies can be combined together to emit the light with the target peak wavelength and packaged. Consequently, the LED package structure enables the human eyes to sense the particular light intensity at the target peak wavelength such that the human eyes feel the light intensity the same as that of two dies for emitting the light with the target peak wavelength. In addition, since the dies may be picked and matched, the package manufacturer can broaden the range of the peak wavelength for the good die. Thus, the die availability on the same wafer or in the same batch can be enhanced, the manufacturing cost may be reduced, and the wastage of the material can be reduced.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a wafer cut into a plurality of dies according to the prior art;

FIG. 2 is a schematic illustration showing a package structure of a light emitting diode according to a first embodiment of the invention;

FIG. 3 is another schematic illustration showing the package structure of the light emitting diode according to the invention;

FIG. 4 is another schematic illustration showing the package structure of the light emitting diode according to the invention;

FIG. 5 is another schematic illustration showing the package structure of the light emitting diode according to the invention;

FIG. 6 is a schematic illustration showing wavelength frequency spectrums outputted by the first die and the second die in the package structure of the light emitting diode of the invention, wherein the difference between the wavelength of the light of the first die and the target peak wavelength is equal to the difference between the wavelength of the light of the second die and the target peak wavelength;

FIG. 7 is another schematic illustration showing wavelength frequency spectrums outputted by the first die and the second die in the package structure of the light emitting diode of the invention, wherein the difference between the wavelength of the light of the first die and the target peak wavelength is unequal to the difference between the wavelength of the light of the second die and the target peak wavelength; and

FIG. 8 is another schematic illustration showing the package structure of the light emitting diode according to a second embodiment of the invention.

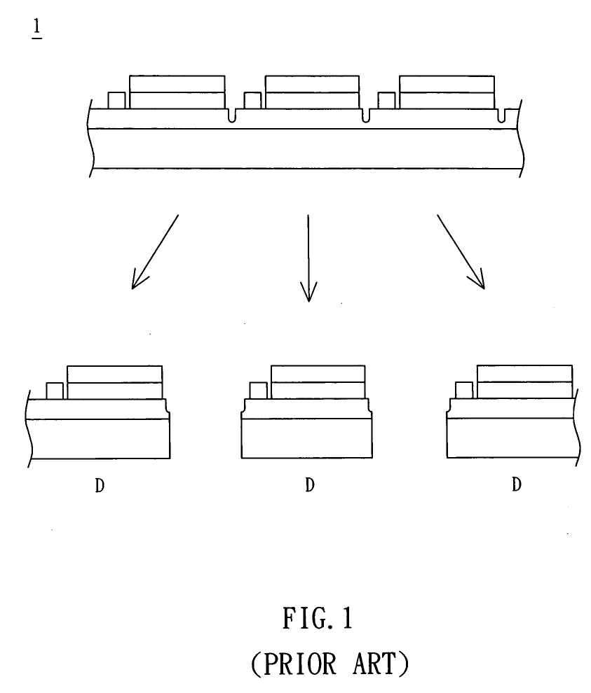

### DETAILED DESCRIPTION OF THE INVENTION

The present invention will be apparent from the following detailed description, which proceeds with reference to the accompanying drawings, wherein the same references relate to the same elements.

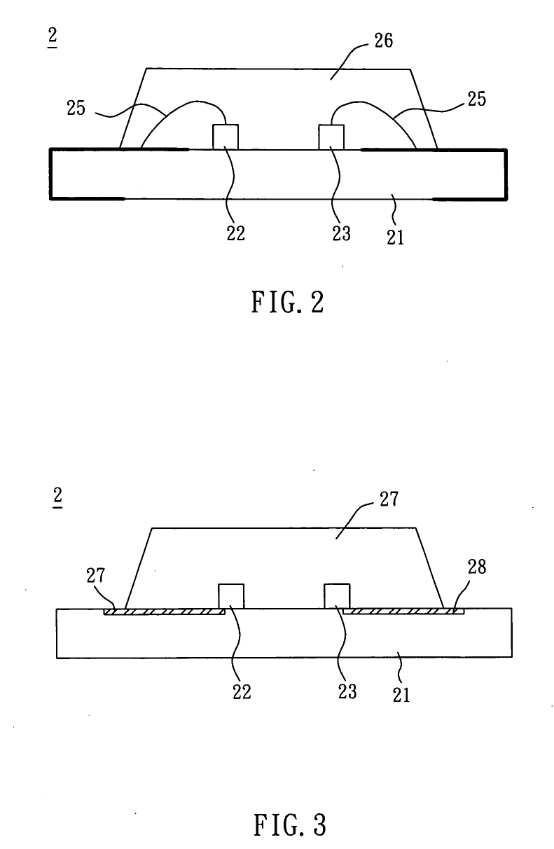

A package structure of a light emitting diode according to the first embodiment of the invention will be described with reference to FIGS. 2 and 3.

Referring to FIG. 2, the package structure 2 of the light emitting diode or a LED package structure 2 includes a carrier 21, a first die 22 and a second die 23. The LED package structure 2 outputs light of a target peak wavelength λₜ, which may be red light having the peak wavelength ranging from 615 nm to 650 nm, green light having the peak wavelength ranging from 515 nm to 555 nm, or blue light having the peak wavelength ranging from 455 nm to 485 nm. That is, the target peak wavelength can be specified by the manufacturer and is the peak wavelength of the LED package structure 2, which may be sensed by the human eye. The LED package structure 2 can output the target peak wavelength according to the persistence of vision of human eyes when the first die 22 and the second die 23 simultaneously or insimultaneously emit light.

Of course, the target peak wavelength of the LED package structure 2 may be defined as ranging from 620.5 nm to 645.0 nm pertaining to first read light (R1), as ranging from 612.5 nm to 620.5 nm pertaining to second red light (R2), as ranging from 520 nm to 550 nm pertaining to first green light (G1), as ranging from 490 nm to 520 nm pertaining to second green light (G2), as ranging from 460 nm to 490 nm pertaining to first blue light (B1), or as ranging from 440 nm to 460 nm pertaining to second blue light (B2).

As shown in FIG. 2, the first die 22 and the second die 23 are disposed on the carrier 21. The carrier 21 may be a substrate or a leadframe. In this embodiment, the package type of the light emitting diode and the material of the substrate are not particularly restricted. For example, the carrier 21 may be a transparent substrate or an opaque substrate. The package type may be the SMD (Surface Mounting Device) type as shown in FIG. 2. The first die 22 and the second die 23 may be electrically connected to the carrier 21 through a plurality of wirings 25 and then an encapsulating material 26 is applied to protect the first die 22 and the second die 23.

As shown in FIG. 3, of course, the first die 22 and the second die 23 may communicate with the outside with electric signals through interconnections 27 on the substrate without wiring. The first die 22 and the second die 23 may also be mounted on the carrier 21 in a flip chip manner.

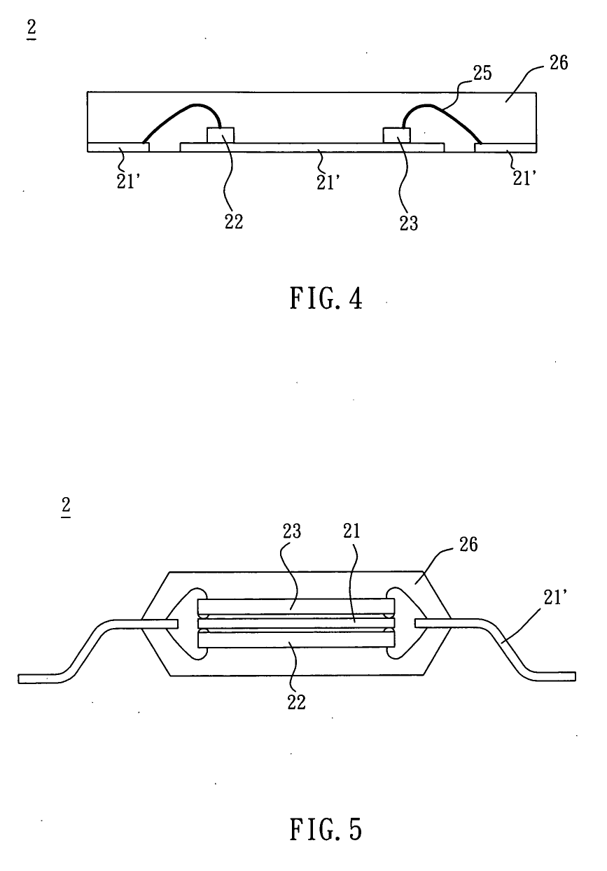

As shown in FIG. 4, when the carrier 21′ is the leadframe, the package becomes the leadframe package. In addition, the first die 22 and the second die 23 of FIG. 5 may be stacked together and then mounted to the substrate and the leadframe serving as the carriers 21 and 21′.

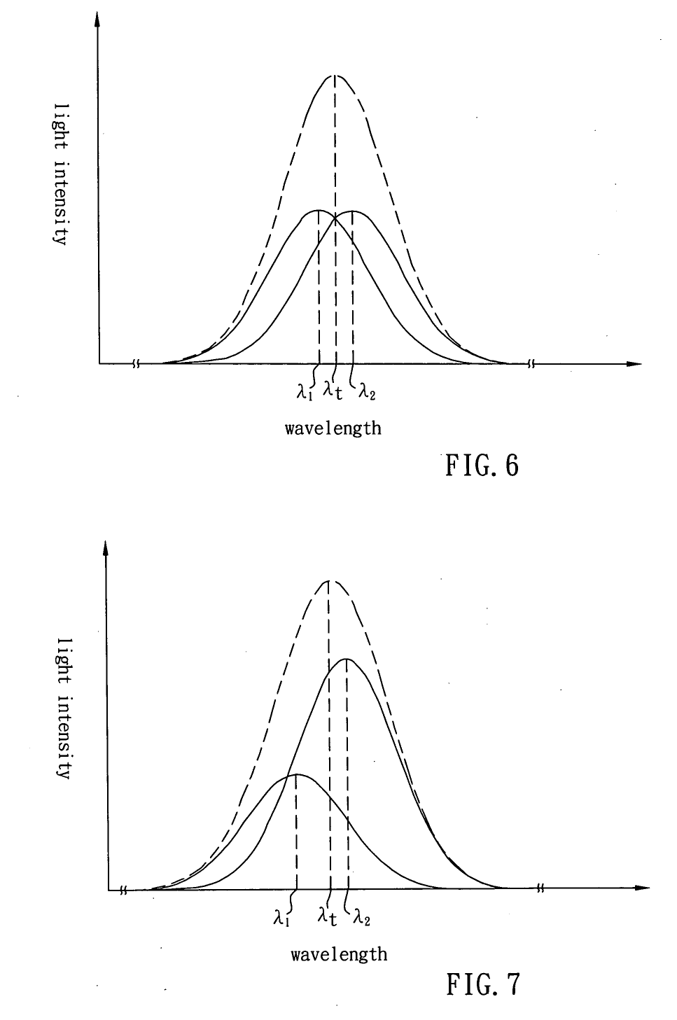

Referring again to FIGS. 2 and 6, the first die 22 has a first peak wavelength λ₁ greater than the target peak wavelength λₜ, and the second die 23 has a second peak wavelength λ₂ smaller than the target peak wavelength λₜ. The light emitted by the first die 22 and the second die 23 pertains to the same color group. For example, the first die 22 and the second die 23 emit the color group of light, such as green and cyan light, and the first die 22 and the second die 23 may be the dies formed on the same wafer. Of course, the first die 22 and the second die 23 may be the dies formed on different wafers but in the same batch. In this embodiment, the first die 22 and the second die 23 are formed on the same wafer.

The peak wavelength of each die must be measured first to pick over the dies for emitting light having the peak wavelengths that can be matched with one another and suitable for being packaged together. The match may occur such that the dies can be placed in the same package structure as long as a difference (Δλ) between the first peak wavelength λ₁ of the first die 22 and the second peak wavelength λ₂ of the second die 23 is smaller than 50 nm.

In the example of this embodiment, the LED package structure 2 outputs the light with the target peak wavelength λₜ of 530 nm. When the difference between the first die 22 and the target peak wavelength is equal to the difference between the second die 23 and the target peak wavelength λₜ (e.g., the first peak wavelength λ₁ is about 535 nm and the second peak wavelength λ₂ is about 525 nm), and the emitting efficiency of the first die 22 is the same as that of the second die 23, providing the same current to the first die 22 and the second die 23 makes the human eyes feel the particular light intensity at the target peak wavelength of 530 nm when either the first die 22 and the second die 23 simultaneously or alternately emit light. Herein, the particular light intensity is the summation of the light intensities of the first die 22 and the second die 23 at the target peak wavelength of 530 nm, as shown in the wavelength frequency spectrum depicted by the dashed line. That is, after the first die 22 and the second die 23 are packaged together according to the wavelength matching, the first die 22 and the second die 23 may work together to emit the light with the target peak wavelength λₜ, such that the human eyes cannot distinguish the wavelength differences between the dies, and the package structure looks like a package having two dies each emitting the light with the target peak wavelength λₜ.

As shown in FIGS. 2 and 7, the example of this embodiment is the LED package structure 2 for outputting the light with the target peak wavelength λₜ of 530 nm. When the difference between the wavelength of the light of the first die 22 and the target peak wavelength is one half that between the wavelength of the light of the second die 23 and the target peak wavelength (e.g., the first peak wavelength λ₁ is about 535 nm and the second peak wavelength λ₂ is about 520 nm) and the first die 22 and the second die 23 have the same light emitting efficiency, the current or voltage value of the first die 22 may be increased as much as twice such that the light intensity of the first die 22 is two times that of the second die 23. As shown in FIG. 7, when the first die 22 and the second die 23 simultaneously or alternately emit light rapidly, the light intensity sensed by the human eyes at the target peak wavelength λₜ is the summation of the light intensities of the first die 22 and the second die 23 at the target peak wavelength λₜ, as shown in the wavelength frequency spectrum depicted by the dashed line.

In a preferred condition, when the difference between the first peak wavelength λ₁ and the second peak wavelength λ₂ is smaller than 30 nm, the combined light intensity at the target peak wavelength is higher and a main peak may be formed. In addition, even if the summated wavelength of the light of the first die 22 and the second die 23 cannot form a single main peak, the human eyes still cannot recognize the loss in color saturation because the light emitted from the light emitting diode is purer.

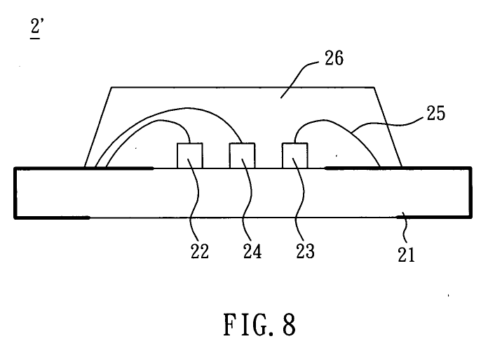

Next, the LED package structure according to the second embodiment of the invention will be described with reference to FIG. 8.

The LED package structure 2′ further includes a third die 24 for emitting light having a third peak wavelength λ₃. The third die 24, the first die 22 and the second die 23 output the light pertaining to the same color group. For example, when the first die 22 and the second die 23 output the pink light, the third die 24 outputs the rose-red light, and the pink light and the rose-red light pertain to the red color group of light.

When the LED package structure 2′ has three dies, the difference between the maximum and minimum peak wavelengths of the dies should be smaller than 50 nm. That is, when the third peak wavelength λ₃ is greater than the first peak wavelength λ₁, the difference between the third peak wavelength λ₃ and the second peak wavelength λ₂ is smaller than 50 nm. When the third peak wavelength λ₃ is smaller than the second peak wavelength λ₂, the difference between the third peak wavelength λ₃ and the first peak wavelength λ₁ is smaller than 50 nm.

In the preferred condition, the difference between the maximum and minimum peak wavelengths should be smaller than 30nm in the plurality of dies of the LED package structure 2′.

Of course, as long as the number of dies is greater than one, the number of dies in the LED package structure of the invention is not particularly restricted.

In summary, the LED package structure of the invention has a plurality of dies having the first peak wavelength and the second peak wavelength, which pertain to the same color group. Compared to the prior art, a plurality of dies having the properly matched wavelengths can be picked in the LED package structure of the invention, so that the dies can be combined together to emit the light with the target peak wavelength and packaged. Consequently, the LED package structure enables the human eyes to sense the particular light intensity at the target peak wavelength such that the human eyes feel the light intensity the same as that of two dies for emitting the light with the target peak wavelength. In addition, since the dies may be picked and matched, the package manufacturer can broaden the range of the peak wavelength for the good die. Thus, the die availability on the same wafer or in the same batch can be enhanced, the manufacturing cost may be reduced, and the wastage of the material can be reduced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A package structure of a light emitting diode for outputting a target peak wavelength, the package structure comprising:
a carrier;
a first die disposed on the carrier and emitting light having a first peak wavelength greater than the target peak wavelength; and
a second die disposed on the carrier and emitting light having a second peak wavelength smaller than the target peak wavelength, wherein the first peak wavelength and the second peak wavelength pertain to the same color group.

2. The structure according to claim 1, wherein the carrier is a substrate or a leadframe.

3. The structure according to claim 1, wherein the first die and the second die emit the light simultaneously or insimultaneously.

4. The structure according to claim 1, wherein a difference between the first peak wavelength and the second peak wavelength is smaller than 50 nm.

5. The structure according to claim 1, wherein a difference between the first peak wavelength and the second peak wavelength is smaller than 30 nm.

6. The structure according to claim 1, wherein a difference between the target peak wavelength and the first peak wavelength is unequal to a difference between the target peak wavelength and the second peak wavelength.

7. The structure according to claim 1, wherein a difference between the target peak wavelength and the first peak wavelength is equal to a difference between the target peak wavelength and the second peak wavelength.

8. The structure according to claim 1, wherein the first die and the second die have different light intensities.

9. The structure according to claim 1, wherein the target peak wavelength substantially ranges from 615 nm to 650 nm.

10. The structure according to claim 1, wherein the target peak wavelength substantially ranges from 515 nm to 555 nm.

11. The structure according to claim 1, wherein the target peak wavelength substantially ranges from 455 nm to 485 nm.

12. The structure according to claim 1, further comprising:
a third die having a third peak wavelength, wherein the first peak wavelength, the second peak wavelength and the third peak wavelength pertain to the color group.

13. The structure according to claim 12, wherein the third peak wavelength is greater than the first peak wavelength, and a difference between the third peak wavelength and the second peak wavelength is smaller than 50 nm.

14. The structure according to claim 12, wherein the third peak wavelength is smaller than the second peak wavelength, and a difference between the third peak wavelength and the first peak wavelength is smaller than 50 nm.
